(19) United States
(12) Patent Application Publication
(10) Pub. No.: US 2011/0143163 A1
(43) Pub. Date: Jun. 16, 2011

(54) Method for the production of an optimized bonding agent layer by means of partial evaporation of the bonding agent layer, and a layer system

(76) Inventors: Knut Halberstadt, Mulheim an der Ruhr (DE); Friedhelm Schmitz, Dinslaken (DE); Eckart Schumann, Mulheim an der Ruhr (DE)

(21) Appl. No.: 12/992,273

(22) PCT Filed: Apr. 7, 2009
(86) PCT No.: PCT/EP09/54127

§ 371 Date: Jan. 26, 2011

(30) Foreign Application Priority Data
May 15, 2008 (EP) 08009023.6

(51) Int. Cl. B32B 15/00; H05H 1/24; C23C 16/06; C23C 16/44

(52) U.S. Cl. 428/656; 427/576

(57) ABSTRACT

Bonding agent layers are often used in heat insulation layers in order to improve the bonding of an outer ceramic layer to a metal substrate. A process is provided wherein a MCrAlX or MCrAl alloy is applied to a substrate whereby an outer layer region within the layer is produced using a heat treatment.

### CROSS REFERENCE TO RELATED APPLICATIONS

This application is the US National Stage of International Application No. PCT/EP2009/054127, filed Apr. 7, 2009 and claims the benefit thereof. The International Application claims the benefits of European Patent Office application No. 08009023.6 EP filed May 15, 2008. All of the applications are incorporated by reference herein in their entirety.

### FIELD OF INVENTION

The invention relates to a process for producing a bonding layer and to a layer system according to the claims.

### BACKGROUND OF INVENTION

In thermal barrier coating systems, use is often made of a metallic bonding layer in order to improve the bond between the outer ceramic thermal barrier coating and the metallic substrate. Single-layer MCrAlX systems or even recently roughened two-layer MCrAlX systems are often used as bonding layers. In this case, the outer MCrAlX layer has a different structure, which contributes in particular to an improvement in resistance to oxidation and corrosion. Said second MCrAlX layer is applied separately, which represents an additional process step and also entails bonding problems. The desired phase of the outer layer cannot always be controlled precisely.

### SUMMARY OF INVENTION

It is therefore an object of the invention to solve the above-mentioned problem.

The object is achieved by a process as claimed in the claims, in which only a single-layer system is applied but is converted into a two-layer system by a heat treatment, and by a layer system as claimed in the claims.

The dependent claims each list further advantageous measures which can be combined with one another, as desired, in order to obtain further advantages.

### BRIEF DESCRIPTION OF THE DRAWINGS

FIG. 1 schematically shows the sequence of the process,

FIGS. 2, 3 show exemplary uses of the layer system produced in this way,

FIG. 4 shows a gas turbine,

FIG. 5 shows a perspective view of a turbine blade or vane,

FIG. 6 shows a perspective view of a combustion chamber, and

FIG. 7 shows a list of superalloys.

The figures and the description represent only exemplary embodiments.

### DETAILED DESCRIPTION OF INVENTION

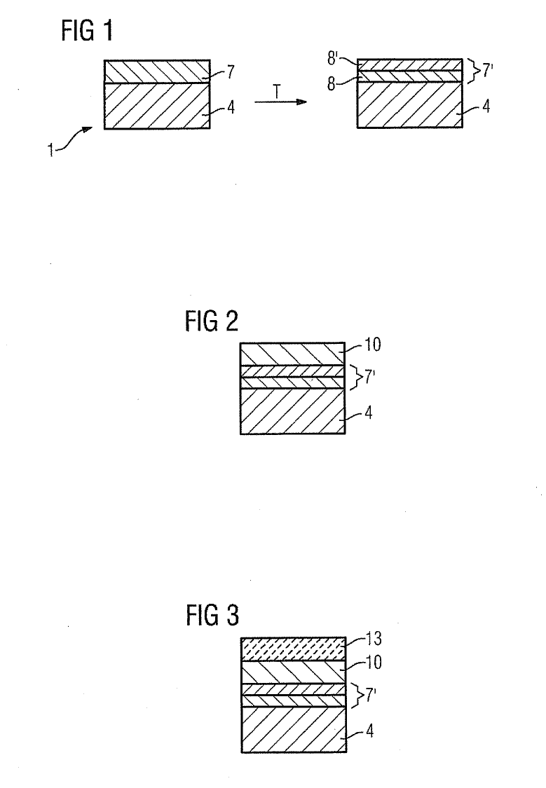

FIG. 1 schematically shows the sequence of the process.

The layer system 1 has a substrate 4 and a metallic layer 7 made of an MCrAlX or MCrAl alloy (M=Ni and/or Co).

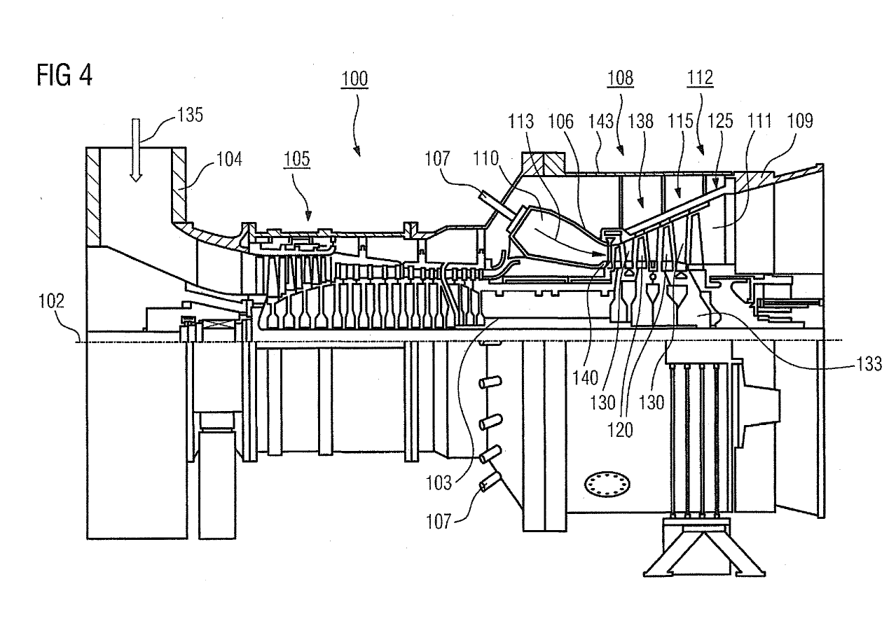

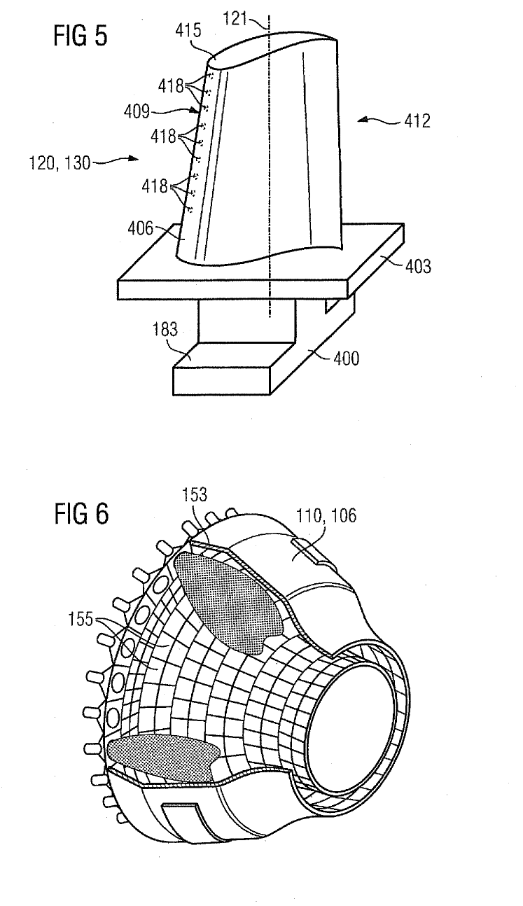

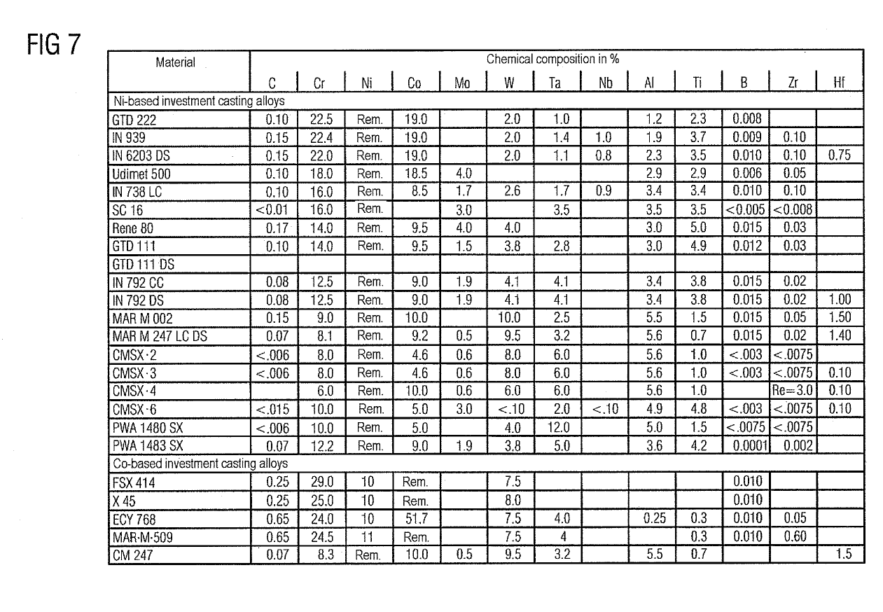

In particular in the case of the component 120, 130, 155 (FIGS. 5, 6) of a gas turbine 100 (FIG. 4), the substrate 4 consists of a superalloy according to FIG. 7.

An MCrAl or MCrAlX layer 7 applied by APS, LPPS, VPS, HVOF or other coating processes is present on the nickel- or cobalt-based superalloy.

X is preferably yttrium (X═Y) and M is preferably Ni and Co.

According to the invention, only one coating operation of the layer 7 takes place with only one powder type.

By virtue of a heat treatment (T) at 1000° C.-1200° C., preferably 1140° C.-1180° C., preferably in a vacuum, the chromium in the MCrAl or MCrAlX alloy evaporates, such that a different chemical composition (reduced chromium content) is present in the outermost layer region 8′.

The duration of the heat treatment is two to eight hours. It is preferable for a different phase to also form, and it is very preferable for a β-NiAl layer to form. The heat treatment is preferably carried out for an accordingly long time.

If appropriate, a second heat treatment which can be distinguished from the chromium evaporation is carried out, in order to carry out the phase transformations of Ni—Al, Ni—Al—Cr, Ni—Al—Co, Ni—Al—Cr—Co to β-NiAl.

The layer 7′ which is changed in this way thus consists of an outer layer region 8′ with a reduced chromium content, preferably of a β-NiAl phase, and an unchanged lower layer region 8, which has the same composition as the originally applied layer 7 but is thinner (thickness of 8′ thickness of 7′ or thickness (8+8′)=thickness (7) or thickness (8+8′)=thickness (7′)).

This heat treatment has two advantages.

On the one hand, a homogeneous single-phase structure is formed on the surface. On the other hand, a homogeneous oxide layer with very small spinel fractions and very small fractions of nickel and/or chromium oxides is formed at high temperatures. The oxide layer thus formed is the starting point for a further homogeneous, thermally grown oxide layer 10 (TGO) (FIGS. 2, 3).

For use as the layer system 1, oxidation can be brought about intentionally or the oxide layer 10 forms during the application of a ceramic outer thermal barrier coating 13 (FIG. 3).

The layer 7′ may likewise be used as an overlay layer, i.e. it forms the outermost layer with the exception of the TGO layer 10 which forms thereon.

The layer region 8′ has therefore not been applied by a second coating operation or not by the change of the powder (from MCrAl to NiAl powder) during the coating operation, and therefore also bonds well to the underlying layer region 8.

FIG. 4 shows, by way of example, a partial longitudinal section through a gas turbine 100.

In the interior, the gas turbine 100 has a rotor 103 with a shaft which is mounted such that it can rotate about an axis of rotation 102 and is also referred to as the turbine rotor.

An intake housing 104, a compressor 105, a, for example, toroidal combustion chamber 110, in particular an annular combustion chamber, with a plurality of coaxially arranged burners 107, a turbine 108 and the exhaust-gas housing 109 follow one another along the rotor 103.

The annular combustion chamber 110 is in communication with a, for example, annular hot-gas passage 111, where, by way of example, four successive turbine stages 112 form the turbine 108.

Each turbine stage 112 is formed, for example, from two blade or vane rings. As seen in the direction of flow of a working medium 113, in the hot-gas passage 111 a row of guide vanes 115 is followed by a row 125 formed from rotor blades 120.

The guide vanes 130 are secured to an inner housing 138 of a stator 143, whereas the rotor blades 120 of a row 125 are fitted to the rotor 103 for example by means of a turbine disk 133.

A generator (not shown) is coupled to the rotor 103.

While the gas turbine 100 is operating, the compressor 105 sucks in air 135 through the intake housing 104 and compresses it. The compressed air provided at the turbine-side end of the compressor 105 is passed to the burners 107, where it is mixed with a fuel. The mix is then burnt in the combustion chamber 110, forming the working medium 113. From there, the working medium 113 flows along the hot-gas passage 111 past the guide vanes 130 and the rotor blades 120. The working medium 113 is expanded at the rotor blades 120, transferring its momentum, so that the rotor blades 120 drive the rotor 103 and the latter in turn drives the generator coupled to it.

While the gas turbine 100 is operating, the components which are exposed to the hot working medium 113 are subject to thermal stresses. The guide vanes 130 and rotor blades 120 of the first turbine stage 112, as seen in the direction of flow of the working medium 113, together with the heat shield elements which line the annular combustion chamber 110, are subject to the highest thermal stresses.

To be able to withstand the temperatures which prevail there, they may be cooled by means of a coolant.

Substrates of the components may likewise have a directional structure, i.e. they are in single-crystal form (SX structure) or have only longitudinally oriented grains (DS structure).

By way of example, iron-based, nickel-based or cobalt-based superalloys are used as material for the components, in particular for the turbine blade or vane 120, 130 and components of the combustion chamber 110.

Superalloys of this type are known, for example, from EP 1 204 776 B1, EP 1 306 454, EP 1 319 729 A1, WO 99/67435 or WO 00/44949; these documents form part of the disclosure with regard to the chemical composition of the alloys.

The guide vane 130 has a guide vane root (not shown here), which faces the inner housing 138 of the turbine 108, and a guide vane head which is at the opposite end from the guide vane root. The guide vane head faces the rotor 103 and is fixed to a securing ring 140 of the stator 143.

FIG. 5 shows a perspective view of a rotor blade 120 or guide vane 130 of a turbomachine, which extends along a longitudinal axis 121.

The turbomachine may be a gas turbine of an aircraft or of a power plant for generating electricity, a steam turbine or a compressor.

The blade or vane 120, 130 has, in succession along the longitudinal axis 121, a securing region 400, an adjoining blade or vane platform 403 and a main blade or vane part 406 and a blade or vane tip 415.

As a guide vane 130, the vane 130 may have a further platform (not shown) at its vane tip 415.

A blade or vane root 183, which is used to secure the rotor blades 120, 130 to a shaft or a disk (not shown), is formed in the securing region 400.

The blade or vane root 183 is designed, for example, in hammerhead form. Other configurations, such as a fir-tree or dovetail root, are possible.

The blade or vane 120, 130 has a leading edge 409 and a trailing edge 412 for a medium which flows past the main blade or vane part 406.

In the case of conventional blades or vanes 120, 130, by way of example solid metallic materials, in particular superalloys, are used in all regions 400, 403, 406 of the blade or vane 120, 130.

Superalloys of this type are known, for example, from EP 1 204 776 B1, EP 1 306 454, EP 1 319 729 A1, WO 99/67435 or WO 00/44949; these documents form part of the disclosure with regard to the chemical composition of the alloy.

The blade or vane 120, 130 may in this case be produced by a casting process, by means of directional solidification, by a forging process, by a milling process or combinations thereof.

Workpieces with a single-crystal structure or structures are used as components for machines which, in operation, are exposed to high mechanical, thermal and/or chemical stresses.

Single-crystal workpieces of this type are produced, for example, by directional solidification from the melt. This involves casting processes in which the liquid metallic alloy solidifies to form the single-crystal structure, i.e. the single-crystal workpiece, or solidifies directionally.

In this case, dendritic crystals are oriented along the direction of heat flow and form either a columnar crystalline grain structure (i.e. grains which run over the entire length of the workpiece and are referred to here, in accordance with the language customarily used, as directionally solidified) or a single-crystal structure, i.e. the entire workpiece consists of one single crystal. In these processes, a transition to globular (polycrystalline) solidification needs to be avoided, since non-directional growth inevitably forms transverse and longitudinal grain boundaries, which negate the favorable properties of the directionally solidified or single-crystal component.

Where the text refers in general terms to directionally solidified microstructures, this is to be understood as meaning both single crystals, which do not have any grain boundaries or at most have small-angle grain boundaries, and columnar crystal structures, which do have grain boundaries running in the longitudinal direction but do not have any transverse grain boundaries. This second form of crystalline structures is also described as directionally solidified microstructures (directionally solidified structures).

Processes of this type are known from U.S. Pat. No. 6,024,792 and EP 0 892 090 A1.

The blades or vanes 120, 130 may likewise have coatings protecting against corrosion or oxidation e.g. (MCrAlX; M is at least one element selected from the group consisting of iron (Fe), cobalt (Co), nickel (Ni), X is an active element and stands for yttrium (Y) and/or silicon and/or at least one rare earth element, or hafnium (Hf)). Alloys of this type are known from EP 0 486 489 B1, EP 0 786 017 B1, EP 0 412 397 B1 or EP 1 306 454 A1.

The density is preferably 95% of the theoretical density.

A protective aluminum oxide layer (TGO=thermally grown oxide layer) is formed on the MCrAlX layer (as an intermediate layer or as the outermost layer).

The layer preferably has a composition Co-30Ni-28Cr-8Al-0.6Y-0.7Si or Co-28Ni-24Cr-10Al-0.6Y. In addition to these cobalt-based protective coatings, it is also preferable to use nickel-based protective layers, such as Ni-10Cr-12Al-0.6Y-3Re or Ni-12Co-21Cr-11Al-0.4Y-2Re or Ni-25Co-17Cr-10Al-0.4Y-1.5Re.

It is also possible for a thermal barrier coating, which is preferably the outermost layer and consists for example of ZrO₂, Y₂O₃—ZrO₂, i.e. unstabilized, partially stabilized or fully stabilized by yttrium oxide and/or calcium oxide and/or magnesium oxide, to be present on the MCrAlX.

The thermal barrier coating covers the entire MCrAlX layer. Columnar grains are produced in the thermal barrier coating by suitable coating processes, such as for example electron beam physical vapor deposition (EB-PVD).

Other coating processes are possible, for example atmospheric plasma spraying (APS), LPPS, VPS or CVD. The thermal barrier coating may include grains that are porous or have micro-cracks or macro-cracks, in order to improve the resistance to thermal shocks. The thermal barrier coating is therefore preferably more porous than the MCrAlX layer.

The blade or vane 120, 130 may be hollow or solid in form. If the blade or vane 120, 130 is to be cooled, it is hollow and may also have film-cooling holes 418 (indicated by dashed lines).

FIG. 6 shows a combustion chamber 110 of the gas turbine 100. The combustion chamber 110 is configured, for example, as what is known as an annular combustion chamber, in which a multiplicity of burners 107, which generate flames 156, arranged circumferentially around an axis of rotation 102 open out into a common combustion chamber space 154. For this purpose, the combustion chamber 110 overall is of annular configuration positioned around the axis of rotation 102.

To achieve a relatively high efficiency, the combustion chamber 110 is designed for a relatively high temperature of the working medium M of approximately 1000° C. to 1600° C. To allow a relatively long service life even with these operating parameters, which are unfavorable for the materials, the combustion chamber wall 153 is provided, on its side which faces the working medium M, with an inner lining formed from heat shield elements 155.

Moreover, a cooling system may be provided for the heat shield elements 155 and/or their holding elements, on account of the high temperatures in the interior of the combustion chamber 110. The heat shield elements 155 are then, for example, hollow and may also have cooling holes (not shown) opening out into the combustion chamber space 154.

On the working medium side, each heat shield element 155 made from an alloy is equipped with a particularly heat-resistant protective layer (MCrAlX layer and/or ceramic coating) or is made from material that is able to withstand high temperatures (solid ceramic bricks).

These protective layers may be similar to the turbine blades or vanes, i.e. for example MCrAlX: M is at least one element selected from the group consisting of iron (Fe), cobalt (Co), nickel (Ni), X is an active element and stands for yttrium (Y) and/or silicon and/or at least one rare earth element or hafnium (Hf). Alloys of this type are known from EP 0 486 489 B1, EP 0 786 017 B1, EP 0 412 397 B1 or EP 1 306 454 A1.

It is also possible for a, for example, ceramic thermal barrier coating to be present on the MCrAlX, consisting for example of ZrO₂, Y₂O₃—ZrO₂, i.e. unstabilized, partially stabilized or fully stabilized by yttrium oxide and/or calcium oxide and/or magnesium oxide.

Columnar grains are produced in the thermal barrier coating by suitable coating processes, such as for example electron beam physical vapor deposition (EB-PVD).

Other coating processes are possible, e.g. atmospheric plasma spraying (APS), LPPS, VPS or CVD. The thermal barrier coating may include grains that are porous or have micro-cracks or macro-cracks, in order to improve the resistance to thermal shocks.

Refurbishment means that after they have been used, protective layers may have to be removed from turbine blades or vanes 120, 130 or heat shield elements 155 (e.g. by sand-blasting). Then, the corrosion and/or oxidation layers and products are removed. If appropriate, cracks in the turbine blade or vane 120, 130 or in the heat shield element 155 are also repaired. This is followed by recoating of the turbine blades or vanes 120, 130 or heat shield elements 155, after which the turbine blades or vanes 120, 130 or the heat shield elements 155 can be reused.

1.-15. (canceled)

16. A process for producing a layer system, comprising:
applying a layer made of an MCrAlX or MCrAl alloy to a substrate using atmospheric plasma spraying or another coating process; and
producing an outer layer region within the layer as a result of chromium evaporating from the MCrAlX or MCrAl alloy of the layer using a heat treatment,
wherein only one powder type is used,
wherein M=Ni or Co, and
wherein the outer layer region includes a reduced chromium content compared to a lower layer region of the layer.

17. The process as claimed in claim 16,
wherein a MCrAlX alloy is used for the layer, and
wherein X is preferably yttrium.

18. The process as claimed in claim 16, wherein a temperature of the heat treatment is 1000° C. to 1200° C.

19. The process as claimed in claim 18, wherein the temperature of the heat treatment is 1140° C. to 1180° C.

20. The process as claimed in claim 19, wherein the temperature of the heat treatment is 1160° C.

21. The process as claimed in claim 20, wherein a vacuum heat treatment is carried out.

22. The process as claimed in claim 21, wherein a duration of the process is 2 h to 8 h.

23. The process as claimed in claim 16, wherein the outer layer region includes a first phase that is different than a second phase of the lower layer region.

24. The process as claimed in claim 16, wherein an oxide layer is formed on the outer layer region of the MCrAlX layer or of the MCrAl layer.

25. The process as claimed in claim 24, wherein a ceramic coating is applied to the oxide layer of the MCrAl layer or of the MCrAlX layer.

26. The process as claimed in claim 16, wherein a vacuum heat treatment is carried out.

27. The process as claimed in claim 16, wherein which the heat treatment is carried out until a β-NiAl phase is produced in the outer layer region.

28. The process as claimed in claim 16, wherein the outer layer region is converted to β-NiAl by a second, different heat treatment.

29. The process as claimed in claim 16, wherein a duration of the process is 2 h to 8 h.

30. The process as claimed in claim 16, wherein a MCrAl alloy is used for the layer.

31. A layer system, comprising:
a substrate; and
a layer on top of the substrate applied by a first coating process, the layer, comprising:
a lower layer region made of a MCrAlX alloy or a MCrAl alloy, and
an outer layer region made of a MCrAlX alloy or a MCrAl alloy including a different chemical composition than the lower layer region,
wherein the outer layer region was not applied in a second coating process.

32. The layer system as claimed in claim 31, the outer layer region is integrally joined to the lower layer region.

33. The layer system as claimed in claim 31, wherein the outer layer region includes a first phase that is different than a second phase of the lower layer region.

34. The layer system as claimed in claim 31, wherein the outer layer region includes a β-NiAl phase.

35. The layer system as claimed in claim 34, wherein the outer layer consists of a β-NiAl phase.
